(19) United States
(12) Patent Application Publication
(10) Pub. No.: US 2001/0045624 A1
(43) Pub. Date: Nov. 29, 2001

(54) HIGH-VOLTAGE SILICON DIODE

(76) Inventors: NORIYUKI IWAMURO, NAGANO (JP); MICHIO NEMOTO, NAGANO (JP); HIROAKI FURIHATA, NAGANO (JP); TAKAHIRO KUBOYAMA, NAGANO (JP)

Correspondence Address: MORRISON LAW FIRM, 145 NORTH FIFTH AVENUE, MOUNT VERNON, NY, 10550

(21) Appl. No.: 09/243,964

(22) Filed: Feb. 3, 1999

(30) Foreign Application Priority Data
Feb. 3, 1998 (JP) 10-021773

(51) Int. Cl. H01L 29/06; H01L 31/0352

(52) U.S. Cl. 257/653

(57) ABSTRACT

A plurality of optimized diode chips are connected in series with each other to provide a high-voltage silicon diode rectifying device. Each chip has an improved withstand voltage and inverse surge resistance which improves the overall usefulness and efficiency of high-voltage silicon diodes. This invention also reduces costs by requiring fewer individual diode chips. The specific resistance of the (n)-type silicon substrate is in a critical range of between 20 to 50 Ωcm. The diffusion depth of the p⁺ anode layer is in a critical range of between 30 to 200 μm. The thickness of the n⁻ base layer is 0.54×(ρ·Vsr)^{½} or greater. In another embodiment, the specific resistance of the silicon substrate is in the range of 32 to 40 Ωcm, and diffusion depth of the p⁺ anode layer is in the range of 70 to 200 μm. In yet another embodiment, a cathode layer is diffused on the semiconductor base material. In another embodiment, a (p)-type semiconductor base material is used to make the diode chips.

### BACKGROUND OF THE INVENTION

The present invention relates to a high-voltage silicon diode comprising a plurality of diode chips having a pn junction optimized to reduce the number of individual diode chips needed to supply power to various electrical devices requiring relatively high voltages. In particular, the present invention is suitable for use as a rectifier in a high-voltage power supply in a cathode-ray tube display.

Conventionally, high-voltage silicon diodes are made by laminating individual diode chips together to rectify an AC high-voltage of up to 20 kV for use in cathode-ray tube displays, microwave ovens, or X-ray apparatus. The diode chips are laminated because it is virtually impossible to form a single chip into a diode capable of withstanding a voltage of 20 kV. This is due to the nature of silicon, the chip's material, and the difficulty of surface treatment. When a positive voltage corresponding to the electric potential difference between the pn junctions is applied to the anode electrode, a current begins to flow through the diode. In contrast, when a negative voltage is applied to the anode electrode, as opposed to the cathode electrode, current through the diode is blocked until an avalanche voltage is applied. This configuration provides a rectifying effect.

If the withstand voltage of the individual diode chips is increased relative to the rated voltage, the number of individual chips needed is reduced. But it is difficult to produce diode chips with such a high withstand voltage. If, however, the withstand voltage of the diode chips is reduced, the chips are much easier to produce, but the number of individual diode chips needed is increased. Conventional diode chips exhibit withstand voltages of approximately 1.3 kV.

There is a growing demand for improvement of the inverse surge resistance of the above high-voltage silicon diode used in high-voltage rectifying circuits. That is, in order to accommodate the increased AC supply frequency of power supplies and internal or external discharges from capacitors, diodes must be protected from destruction even if an avalanche current higher than the specified value is applied. To improve the inverse surge resistance, the specific resistance of the silicon substrate, that is, the (n) base layer of the diode chip having a pn junction, is reduced to improve the breakdown strength. The decrease in the specific resistance of the (n) base layer reduces the breakdown voltage of the diode chip, thereby requiring an increase in the number of chips.

### OBJECTS AND SUMMARY OF THE INVENTION

An object of this invention is to provide a high-voltage silicon diode that overcomes the above tradeoff relationship by exhibiting a high inverse surge resistance that is relatively easy to produce. Having diode chips with a high surge resistance reduces the number of individual chips required.

The present invention provides high-voltage silicon diodes using individual diode chips with an n⁻ base layer that has a specific resistance in a critical range of between 20 to 50 Ωcm. The present invention results in high-voltage silicon diodes that have an inverse surge resistance of 3.85 J and a withstand voltage of 1.485 kV. These values are at least 10% higher than conventional high-voltage silicon diodes.

Briefly stated, the present invention provides a plurality of optimized diode chips connected in series with each other to provide a high-voltage silicon diode rectifying device. Each chip has an improved withstand voltage and inverse surge resistance which improves the overall usefulness and efficiency of high-voltage silicon diodes. This invention also reduces costs by requiring fewer individual diode chips. The specific resistance of the (n)-type silicon substrate is in a critical range of between 20 to 50 Ωcm. The diffusion depth of the p⁺ anode layer is in a critical range of between 30 to 200 μm. The thickness of the n⁻ base layer must be 0.54×(ρ·Vsr)^{½} or greater. In another embodiment, the specific resistance of the silicon substrate is in the range of 32 to 40 Ωcm, and diffusion depth of the p⁺ anode layer is in the range of 70 to 200 μm. In yet another embodiment, a cathode layer is diffused on the semiconductor base material. In another embodiment, a (p)-type semiconductor base material is used to make the diode chips.

According to an embodiment of the invention, there is provided a high-voltage silicon diode comprising: a plurality of semiconductor type diode chips each having two ends which are electrically and physically connected to each other with a conductive bonding material forming electrodes at the ends, the semiconductor type diode chips having a substrate, and the substrate having a thickness of at least 0.54×(ρ·Vsr)^{½} where Vsr is equal to the inverse surge voltage, and having a lead attached with conductive bonding material to outermost exposed ends of the connected diode chips, and the diode chips are surrounded with a passivation layer and physically laminated together with an insulating resin.

The above, and other objects, features and advantages of the present invention will become apparent from the following description read in conjunction with the accompanying drawings, in which like reference numerals designate the same elements.

### BRIEF DESCRIPTION OF THE DRAWINGS

FIG. 1 is a characteristic diagram showing the dependence of the withstand voltage and inverse surge resistance of a single diode chip on the specific resistance of an n⁻ base layer.

FIG. 2 is a characteristic diagram showing the dependence of the withstand voltage and inverse surge resistance of a single diode chip on the diffusion depth of a p⁺ anode layer.

FIG. 3 is a characteristic diagram showing the dependence of the withstand voltage and inverse surge resistance of a single diode chip on the thickness of the n⁻ base layer.

FIG. 4 is another characteristic diagram showing the dependence of the inverse surge resistance on the thickness of the n⁻ base layer.

FIG. 5(a) is a sectional view of a high-voltage silicon diode.

FIG. 5(b) is an enlarged sectional view of individual diode chips laminated together.

FIG. 6 shows the distribution of the concentration of impurities in a diode chip.

### DETAILED DESCRIPTION OF THE PREFERRED EMBODIMENTS

To achieve the objects described above, the present invention provides a high-voltage silicon diode comprising a plurality of p⁺ n-type diode chips laminated together. Each of diode chip includes a p⁺ anode layer formed on an n⁻ type silicon substrate by diffusion. The specific resistance ρ of the silicon substrate is 20 to 50 Ωcm, and the diffusion depth of the p⁺ anode layer is 30 to 200 μm. When the inverse surge voltage to be withstood is defined as Vsr, the thickness Wn of the (n) base layer of the substrate is 0.54×(ρ·Vsr)^{½} or greater.

Another embodiment of the invention provides that the specific resistance ρ of the silicon substrate is 32 to 40 Ωcm and the diffusion depth of the p+ anode layer is 70 to 200 μm. The withstand voltage of a single chip is increased to 1,485 V or greater and the inverse voltage resistance is increased to 3.85 J or greater.

If it is assumed that after the occurrence of a breakdown caused by an intensifying avalanche, the maximum electric field strength in a depletion layer does not exceed the maximum electric field strength Ec of the silicon substrate, and that the gradient dE/dx of the electric field strength in the depletion layer remains unchanged, then the following equation is established:

(qNd−I/v)−x=∈Ec (I)

wherein:

I is the electron current density,

Nd is the donor concentration of

the n⁻ base layer,

v is the electron saturation speed,

and

∈ is the product of the dielectric constant of Silicon and the dielectric constant of a vacuum.

The width, Wb, of the depletion layer generated during the application of a static voltage is expressed by the following equation:

Wb=∈Ec/qNd (II)

Thus, an inverse surge current density I, can be expressed as follows:

I=qvNd(1−Wb/Ws) (III)

wherein:

Ws designates the width of the depletion layer generated during the application of a surge voltage.

This is the width of a depletion layer through which an electron current flows when a dynamic surge voltage is applied. It is not the width of the depletion layer generated under static conditions.

In order to allow a larger current to flow when the surge voltage is applied, Wb/Ws, shown above, is minimized. This allows a larger amount of inverse surge current to flow, thereby increasing the inverse surge resistance.

The results of experiments according to this invention are described below.

On a plurality of (n)-type silicon wafers arbitrarily selected and having a thickness of 420 μm and a specific resistance of 15 to 60 Ωcm, boron is diffused from one side of the wafer to form a p⁺ anode layer. Phosphorous is diffused from the other side to form an n⁺ cathode layer. If, prior to thermal diffusion, a source containing acceptor impurities is coated on one side while a source containing donor impurities is coated on the other side, then the p⁺ anode layer will be almost as thick as the n⁺ cathode layer. This reduces the time required for the process. This process produces silicon wafers which are diffused with platinum in order to ensure a satisfactory life span. The silicon wafers are subsequently plated with nickel and thermally treated. A plurality of silicon wafers (for example, ten) are then laminated together. Wax materials are adhered to the respective ends of the wafers, and the wafers are cut using a wire saw to form a cylindrical body. This cylindrical body is then chemically treated in a mixed acid or an alkali solution to eliminate cutting distortion. Next, leads are connected to the respective ends of the cylindrical body, and a passivation layer of polyimide is formed coating the cylindrical body. An insulating resin such as an epoxy resin is then used to seal the entire assembly.

The diffusion depth of the p⁺ anode layer is 100 μm, and the diffusion depth of the n cathode layer is 100 μm. The concentration of surface impurities in both diffusion layers is 10¹⁹ to 10²⁰ cm⁻³. A 220 μm n⁻ base layer remains between the two diffusion layers. According to this embodiment, the chip size is 1.5 mm². Ten diode chips are laminated together in series.

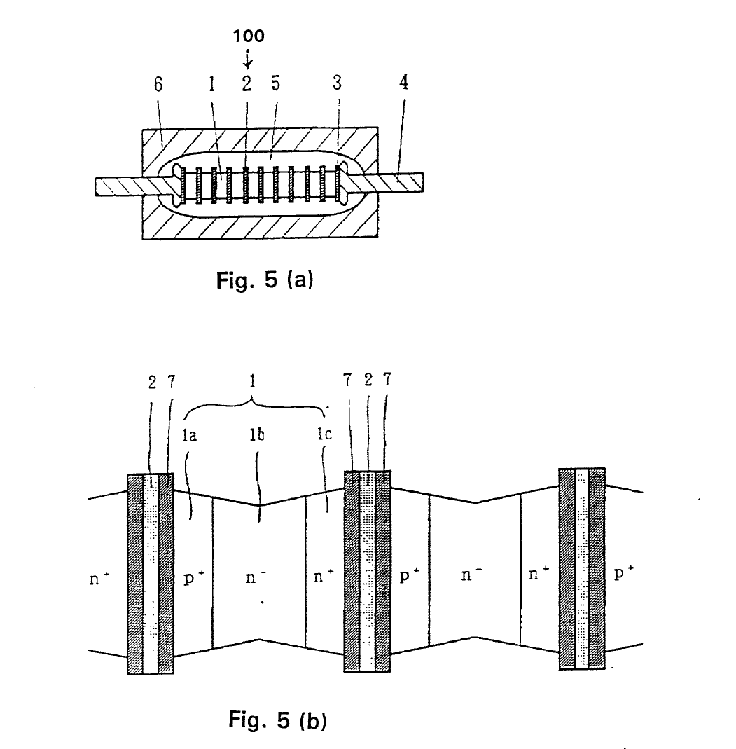

Referring to FIG. 5(a), a high-voltage silicon diode, shown generally at 100, includes a plurality of diode chips 1 laminated terminal to terminal using lead-tin solder 2. Leads 4 are affixed to respective ends of the high-voltage silicon diode 100 with brazing material 3. A passivation layer 5 protects the surfaces of the diode chips 1. A sealing resin 6, such as an epoxy resin, encases the diode chips 1 and the passivation layer 5. In this embodiment, ten diode chips 1 are laminated into a stack. Since one diode chip 1 can withstand a voltage of 1.3 kV, 10-chip high-voltage silicon diode 100 can withstand a voltage of 13 kV. Thus, this configuration provides a diode for rectification in a high-voltage power supply.

Referring to FIG. 5(b), the diode chips 1 are pn diodes made from an (n)-type silicon wafer substrate 1b having a p⁺ anode layer 1a and an n⁻ cathode layer 1c formed on the respective sides. Electrodes 7 are formed over the ends of each diode chip 1. The exposed surface portions of the diode chip 1 that are joined to electrodes 7 are etched using a highly concentrated acid or alkali solution. This removes distortions generated during processing, and also bevels the edges of the chip which increases the withstand voltage. The process is repeated on a plurality of diode chips 1 which are laminated together in series using lead-tin solder 2.

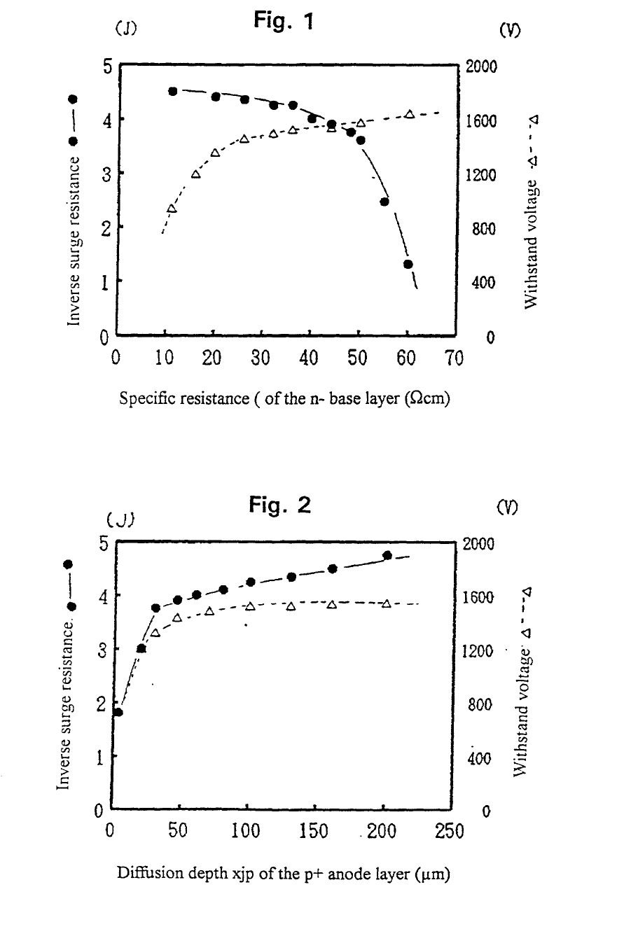

Referring to FIG. 1, the horizontal axis indicates the specific resistance ρ of the n⁻ base layer 1b of FIG. 5(b). The left vertical axis indicates the withstand voltage, shown by the triangles and the broken line. The right vertical axis indicates the inverse surge resistance, shown by the solid circles and the solid line, of a single diode chip 1 of FIG. 5(b). This shows the dependence of the withstand voltage and the inverse surge resistance of a single diode chip 1 of FIG. 5(b) on the specific resistance of the n⁻ base layer 1b of FIG. 5(b). Measurements are evaluated based on the loss that occurs when a voltage of 20 kV and a pulse of 1 ms is applied. The inverse surge resistance is considered high if the maximum loss measured before the high-voltage diode catastrophically fails is large. Since ten diode chips 1 of FIG. 5(a) are connected together in series, the surge voltage applied to a single diode chip 1 of FIG. 5(b) is 2.0 kV.

Still referring to FIG. 1, the withstand voltage of a single diode chip 1 of FIG. 5(b) increases with an increase in the specific resistance of the n⁻ base layer 1b of FIG. 5(b). Conversely, the inverse surge resistance decreases with an increase in the specific resistance of the n⁻ base layer 1b of FIG. 5(b). As is apparent from equation III in the preceding section, when the specific resistance of the n⁻ base layer 1b of FIG. 5(b) is 50 Ωcm or more, the inverse surge resistance degrades rapidly. This is due to the fact that increasing the specific resistance of the n⁻ base layer 1b of FIG. 5(b) increases the width Wb of a depletion layer generated during the application of a static voltage, while the width Ws of a depletion layer that spreads during the application of a rapid surge voltage does not significantly depend on the specific resistance of the n⁻ base layer 1b of FIG. 5(b). The relative independence of Ws is due to the effect of electrons flowing through the depletion layer.

Device simulation was carried out, and the following results were obtained:

When the specific resistance ρ of the n⁻ base layer 1b of FIG. 5(b)=36 Ωcm, Wb=114 μm, Ws=213 μm, and 1−(Wb/Ws)=0.465.

When the specific resistance ρ of the n− base layer 1b of FIG. 5(b)=40 Ωcm, Wb=128 μm, Ws=215 μm, and 1−(Wb/Ws)=0.405.

These results show that the inverse surge resistance decreases with an increase in the specific resistance of the n⁻ base layer 1b of FIG. 5(b).

Furthermore, FIG. 1 also shows that the withstand voltage of the diode chip 1 rapidly degrades when the specific resistance of the n⁻ base layer 1b of FIG. 5(b) decreases below 20 Ωcm. Thus, in order to obtain optimum characteristics, the n⁻ base layer 1b of FIG. 5(b) should be set between 20 to 50 Ωcm which will insure that the withstand voltage and the inverse surge resistance will be in the optimal range of 1.4 kV or greater and 3.5 J or greater, respectively.

In a particular embodiment, when the specific resistance is between 32 and 40 Ωcm, the inverse surge resistance and the withstand voltage are 3.85 J and 1.485 kV, respectively. These values are at least 10% higher than the corresponding values for conventional high-voltage silicon diodes, which are 3.5 J and 1.350 kV, respectively. Thus, this configuration reduces the number of laminated diode chips 1 of FIG. 5(a) connected together in series, thereby reducing costs.

Although in the above embodiment, the p⁺ anode layer 1a of FIG. 5(b) and the n⁺ cathode layer 1c of FIG. 5(b) are simultaneously formed to have a nearly equal diffusion depth, in other embodiments, the thickness of the n⁺ cathode layer 1c of FIG. 5(b) may be decreased to 20 μm or less.

Referring to FIG. 2, the right vertical axis indicates the withstand voltage, and the left vertical axis shows the inverse surge resistance of a single diode chip 1 of FIG. 5(b). This shows the dependence of the withstand voltage (indicated by the triangles and the broken line) and inverse surge resistance (indicated by the solid circles and the solid line) of a single diode chip 1 of FIG. 5(b) on the diffusion depth of the p⁺ anode layer 1a of FIG. 5(b). The horizontal axis indicates the diffusion depth xjp of the p⁺ anode layer 1a of FIG. 5(b). In the production of diode chips 1 of FIG. 5(b), the specific resistance ρ of the n⁻ base layer 1b of FIG. 5(b) and its thickness Wn were set at 36 Ωcm and 220 μm, respectively. The other items are set at the same values as in Experiment 1. Measurements are executed in the same manner as in Experiment 1.

FIG. 2 also shows that the withstand voltage increases with an increase in the diffusion depth xjp of the p⁺ anode layer 1a of FIG. 5(b). This is because increasing the diffusion depth xjp of the p⁺ anode layer 1a of FIG. 5(b) reduces the gradient of the concentration of impurities near the pn junction of diode chip 1 of FIG. 5(b). This causes a depletion layer to spread beyond the n⁻ base layer 1b of FIG. 5(b) into the p⁺ anode layer 1a of FIG. 5(b). This, in turn, enlarges the entire depletion layer despite the fact that Wn remains unchanged.

Also referring to FIG. 2, the withstand voltage remains at 1.4 kV or greater while xjp is 30 μm or greater, and gradually increases until xjp reaches 200 μm, which was the experimental limit. In addition, the inverse surge resistance increases with an increase in the diffusion depth xjp of the p⁺ anode layer 10a of FIG. 5(b). The inverse surge resistance remains at 3.5 J or greater when xjp is 20 μm or greater, and gradually increases until xjp reaches 200 μm, which was the experimental limit. This is because increasing the diffusion depth xjp increases the withstand voltage, which reduces the avalanche current generated during the application of the surge voltage, as described above. Thus, the diffusion depth of the p⁺ anode layer 1a of FIG. 5(b) must be increased in order to maintain good withstand voltages as well as high inverse surge resistance characteristics. In this embodiment, when the diffusion depth of the p⁺ anode layer 1a of FIG. 5(b) is 70 μm or greater, the inverse surge resistance and the withstand voltage are 3.85 J and 1.485 kV, respectively. These values are at least 10% higher than the corresponding values for conventional high-voltage silicon diodes. Thus, this configuration reduces the number of laminated diode chips 1 of FIG. 5(a) connected together in series, thereby reducing costs.

To increase the diffusion depth xjp of the p⁺ anode layer 1a of FIG. 5(b) beyond 200 μm, at least 480 hours (20 days), are required for diffusion at 1,250° C. This is not practical in terms of productivity. When the diffusion depth of the p⁺ anode layer 1a of FIG. 5(b) is 30 μm or less, both the withstand voltage and inverse surge resistance decrease rapidly.

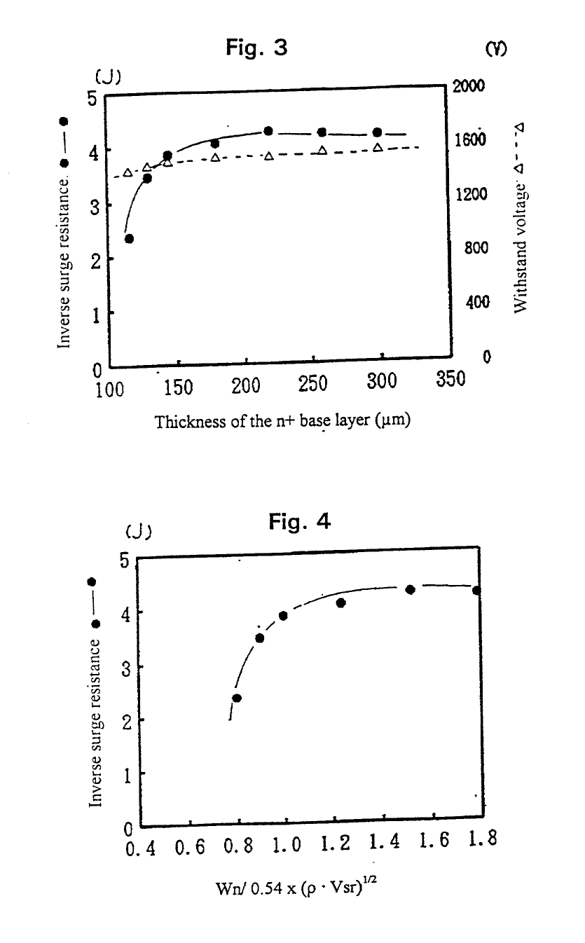

Referring to FIG. 3, the withstand voltage (indicated by the triangles and the broken line) and the inverse surge resistance (indicated by the solid circles and the solid line) of a single diode chip 1 of FIG. 5(b) are dependent on the thickness of the n⁻ base layer 1b of FIG. 5(b). The horizontal axis indicates the thickness Wn of the n⁻ base layer 1b of FIG. 5(b). The vertical axes indicates the withstand voltage and inverse surge resistance of a single diode chip 1 of FIG. 5(b). In this embodiment, the production of diode chips 1 of FIG. 5(b) with a specific resistance ρ of the n⁻ base layer 1b of FIG. 5(b) and a diffusion depth xjp of the p⁺ anode layer 1a of FIG. 5(b) are set at 36 Ωcm and 100 μm, respectively. All other conditions are set at the same values as in Experiment 1. Measurements are executed in the same manner as in Experiment 1.

The withstand voltage does not vary significantly within the experimental range of the thickness of the n⁻ base layer 1b of FIG. 5(b), whereas the inverse surge resistance decreases rapidly when Wn falls below 145 μm. That is, in this embodiment, the thickness of the n⁻ base layer 1b of FIG. 5(b) should be 145 μm or greater.

The applied inverse surge voltage is also 20 kV. According to this embodiment, ten diode chips 1 of FIG. 5(a) are connected in series, so the surge voltage applied to a single diode chip 1 of FIG. 5(b) is 2 kV. When the surge voltage is defined as Vsr, a thickness of the n⁻ base layer 1b of FIG. 5(b) of 145 μm corresponds to 0.54×(ρ·Vsr)^{½}, which is the width of the depletion layer that spreads during the application of the inverse surge voltage where ρ designates the specific resistance of the n⁻ base layer 1b of FIG. 5(b).

Referring to FIG. 4, the horizontal axis indicates the thickness Wn of the n⁻ base layer 1b of FIG. 5(b) standardized relative to 0.54×(ρ·Vsr)^{½}. The vertical axis indicates the inverse surge resistance of a single diode chip 1 of FIG. 5(b). This shows the dependence of the inverse surge resistance on the thickness of the n⁻ base layer 1b of FIG. 5(b)

Also referring to FIG. 4, this embodiment shows that when the thickness Wn of the n⁻ base layer 1b of FIG. 5(b) is less than the width of the depletion layer that spreads during the application of the surge voltage, the inverse surge resistance decreases rapidly. This is because the depletion layer punches through the n⁺ cathode layer 1c of FIG. 5(b). Following this punch-through, Ws no longer increases, while the value of Wb/Ws in Equation (I) increases, thereby reducing the inverse surge resistance. Thus, when the specific resistance of the n⁻ base layer 1b of FIG. 5(b) and the surge voltage are defined as ρ and Vsr, respectively, the thickness of the n⁻ base layer 1b of FIG. 5(b) should be 0.54×(ρ·Vsr)^{½} or greater.

Referring to FIGS. 1-4, taken as a whole, these diagrams show that when the specific resistance ρ is 20 Ωcm or greater, the diffusion depth of the p⁺ anode layer 1a of FIG. 5(b) is 30 μm or more, and the thickness of the n⁻ base layer 1b of FIG. 5(b) has a specific resistance of 0.54×(ρ·Vsr)^{½} or greater. The depletion layer is first accommodated within the n⁻ base layer 1b of FIG. 5(b). Next, the gradient of the concentration of impurities in the pn junction decreases to spread the depletion layer beyond the n⁻ base layer 1b of FIG. 5(b) into the p⁺ anode layer 1a of FIG. 5(b). This reduces the electric field strength which increases the withstand voltage of a single chip 1 of FIG. 5(b) to 1.4 kV or greater.

When the specific resistance ρ is less than 20 Ωcm and the diffusion depth of the p⁺ anode layer 1a of FIG. 5(b) is less than 30 μm, the withstand voltage does not reach 1.4 kV. Likewise, when the specific resistance ρ exceeds 50 Ωcm, the inverse surge resistance decreases rapidly. In order to make the diffusion depth of the p⁺ anode layer 1a of FIG. 5(b) 200 μm or greater, the diffusion must last 480 hours or longer, which is not practical.

A p⁺ anode layer 1a of FIG. 5(b) and an n⁺ cathode layer 1c of FIG. 5(b) are formed on an n⁻ base layer 1b of FIG. 5(b) by means of diffusion in order to provide a p⁺ nn⁺ type diode chip. This configuration reduces the resistance caused by contact with the electrode.

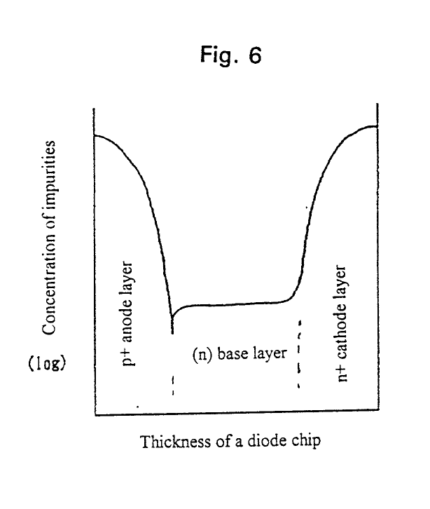

Referring now to FIG. 6, the horizontal axis indicates the thickness of the diode chip 1 of FIG. 5(a). The vertical axis indicates the concentration of impurities. A logarithmic scale is used. Boron and phosphorus are diffused approximately 60 μm from the respective sides of the n⁻ base layer 1b of FIG. 5(b) having a specific resistance of 35 Ωcm and a thickness of 260 μm, in order to form the p⁺ anode layer 1a of FIG. 5(a) and the n+cathode layer 1c FIG. 5(a). The concentration of surface impurities in both diffusion layers is 10¹⁹ to 10²⁰ cm⁻³. The thickness of the intermediate n⁻ base layer not diffused is 140 μm. In another embodiment, a p type silicon substrate (not shown in the figure) that has a p base layer (not shown n the figure) may be used.

Referring again to FIG. 5(a) and FIG. 5(b), this embodiment of the invention provides a high-voltage silicon diode 100 comprising a plurality of diode chips 1 laminated therein, with each of the diode chips having a p⁺ anode layer 1a formed on an n⁻ base layer 1b by means of diffusion. The specific resistance ρ of the n⁻ base layer 1b is between 20 to 50 Ωcm, and the diffusion depth of the p⁺ anode layer 1a is between 30 to 200 μm. In yet another embodiment, the specific resistance is preferred to be between 32 to 40 Ωcm, and the diffusion depth of the p⁺ anode layer 1a is preferred to be between 70 to 200 μm. In both embodiments the inverse surge voltage to be withstood is defined as Vsr, and the thickness Wn of the n⁻ base layer 1b is 0.54×(ρ·Vsr)^{½} or greater. This configuration provides a high-voltage silicon diode with a higher withstand voltage and inverse surge resistance than in the prior art. As a result, the number of laminated diode chips 1 connected in series can be decreased, thereby reducing costs. This will contribute to an increased use of such high-voltage silicon diodes.

Having described preferred embodiments of the invention with reference to the accompanying drawings, it is to be understood that the intention is not limited to those precise embodiments, and that various changes and modifications may be effected therein by one skilled in the art without departing from the scope or spirit of the invention as defined in the appended claims.

What is claimed is:

1. A high-voltage silicon diode comprising:
a plurality of semiconductor type diode chips electrically and physically connected to each other end to end to form a stack;
an electrodes affixed at extreme ends of said stack;
each of said semiconductor type diode chips having a substrate;
said substrate having a thickness of at least 0.54×(ρ·Vsr)^{½} where Vsr is equal to the inverse surge voltage;
a passivation layer surrounding said stack; and
an insulating resin physically laminated said stack together.

2. A high-voltage silicon diode according to claim 1, wherein:
each of said semiconductor type diode chips has at least an n⁻ anode layer formed by diffusion on an (p)-type silicon substrate; and
said (p)-type silicon substrate has a thickness of at least 0.54×(ρ·Vsr)^{½} where Vsr is equal to the inverse surge voltage.

3. A high-voltage silicon diode according to claim 1, wherein:
each of said semiconductor type diode chips has at least a p⁺ anode layer formed by diffusion on an (n)-type silicon substrate; and
said (n)-type silicon substrate has a thickness of at least 0.54×(ρ·Vsr)^{½} where Vsr is equal to the inverse surge voltage.

4. A high-voltage silicon diode according to claim 2, wherein:
each of said semiconductor type diode chips is made from said (p)-type silicon substrate that has a specific resistance, ρ, of between 20 to 50 Ωcm; and
said (p)-type silicon substrate has a diffusion depth of said n⁻ anode layer of between 30 to 200 μm.

5. A high-voltage silicon diode according to claim 2, wherein:
each of said semiconductor type diode chips is made from said (p)-type silicon substrate that has a specific resistance, ρ, of between 32 to 40 Ωcm; and
said (p)-type silicon substrate has a diffusion depth of said n⁻ anode layer of between 70 to 200 μm.

6. A high-voltage silicon diode according to claim 3, wherein:
each of said semiconductor type diode chips is made from said (n)-type silicon substrate that has a specific resistance, ρ, of between 20 to 50 Ωcm; and
said (n)-type silicon substrate has a diffusion depth of said p⁺ anode layer of between 30 to 200 μm.

7. A high-voltage silicon diode according to claim 3, wherein:
each of said semiconductor type diode chips is made from said (n)-type silicon substrate that has a specific resistance, ρ, of between 32 to 40 Ωcm; and
said (n)-type silicon substrate has a diffusion depth of said p⁺ anode layer of between 70 to 200 μm.

8. A high-voltage silicon diode according to claim 4, wherein said semiconductor diode chip has an p⁻ cathode layer formed by diffusion on said (p)-type silicon substrate by means of diffusion to provide an n⁻ pp⁻-type diode chip.

9. A high-voltage silicon diode according to claim 5, wherein said semiconductor diode chip has an p⁻ cathode layer formed by diffusion on said (p)-type silicon substrate by means of diffusion to provide an n⁻pp⁻-type diode chip.

10. A high-voltage silicon diode according to claim 6, wherein said semiconductor diode chip has an n⁺ cathode layer formed by diffusion on said (n)-type silicon substrate by means of diffusion to provide a p⁺nn⁺-type diode chip.

11. A high-voltage silicon diode according to claim 7, wherein said semiconductor diode chip has an n⁺ cathode layer formed by diffusion on said (n)-type silicon substrate by means of diffusion to provide a p⁺nn⁺-type diode chip.
